(19) United States
(12) Patent Application Publication
(10) Pub. No.: US 2011/0156057 A1
(43) Pub. Date: Jun. 30, 2011

(54) SUBSTRATE OF THE SEMICONDUCTOR ON INSULATOR TYPE WITH INTRINSIC AND DOPED DIAMOND LAYERS

(75) Inventors: Jean-Paul Mazellier, Reims (FR); Francois Andrieu, Grenoble (FR); Philippe Bergonzo, Massy (FR); Samuel Saada, Bourg La Reine (FR)

(73) Assignee: COMM. A L'ENERGIE ATOMIQUE ET AUX ENERGIES ALT., Paris (FR)

(21) Appl. No.: 13/055,793

(22) PCT Filed: Jul. 28, 2009
(86) PCT No.: PCT/EP2009/059762

§ 371 Date: Mar. 2, 2011

(30) Foreign Application Priority Data
Jul. 29, 2008 (FR) 0855207

(51) Int. Cl. H01L 29/16; H01L 21/20

(52) U.S. Cl. 257/77; 438/105; 257/E29.082; 257/E21.09

(57) ABSTRACT

A semiconductor substrate including at least a layer based on doped diamond with a thickness greater than or equal to approximately 10 μm, a layer based on at least one semiconductor or a stack of layers including the semiconductor-based layer, and a layer based on intrinsic diamond disposed against the layer based on doped diamond, between the layer based on doped diamond and the semiconductor-based layer.

### TECHNICAL FIELD

The invention concerns a substrate of the semiconductor on insulator type with intrinsic diamond and doped diamond layers, as well as a method of producing such a substrate. The invention also concerns an electronic circuit comprising such a substrate, as well as a method of producing this circuit.

### PRIOR ART

In Bulk technology, the active areas of the CMOS devices are not electrically insulated from the substrate, which gives rise to the presence of leakage currents from these active areas to the substrate. In addition, the stray capacitances present at the source-substrate and drain-substrate junctions may be high and limit the operating frequency of these devices. On the other hand, Bulk technology affords good discharge of heat from the semiconductor devices to the substrate, which has high thermal conductivity (equal to approximately 150 W/m/K for a silicon substrate).

SOI (silicon on insulator) technology or more generally semiconductor on insulator technology, through the presence of a buried dielectric layer (called BOX, and generally based on SiO₂) between a solid or thick layer of semiconductor and an active semiconductor layer (for example silicon), makes it possible to obtain better electrostatic control and a reduction in the stray capacitances in semiconductor devices, for example CMOS (complementary metal oxide semiconductor) transistors, implemented on such substrates, compared with similar semiconductor devices implemented on a solid semiconductor substrate (Bulk technology).

For producing so-called fully depleted or FDSOI transistors, that is to say transistors wherein the channels are formed in an active layer of lightly doped silicon (advantageously 10¹⁵ cm⁻³, but maybe higher) the thickness of which is less than 100 nm, the use of SOI substrates also poses problems. This is because fringing-fields phenomena (source—rear interface and drain—rear interface electrical couplings through the BOX) appear in SOI technology. The active layer of silicon behaves like a capacitance: the rear interface of the active layer with the BOX and the front face of the active layer with the gate insulator of the transistor are therefore coupled by electrostatics, the potential of the rear face of the active layer therefore being able to modify the potential of the front face of the active layer. Only the presence of an additional electrical contact at the rear of the BOX may limit this effect (preferentially capturing the field lines compared with the rear interface).

A thick BOX (having for example a thickness greater than approximately 100 nm for a SiO₂ BOX) makes it possible to obtain weak coupling between the rear face of the active layer and the solid layer of silicon, but the rear source-interface and rear drain-interface coupling increases through the reinforced fringing-field effect. A very fine BOX (thickness less than approximately 50 nm) implies a very strong coupling between the rear face of the active layer and the solid layer of silicon, which also implies a strong source-substrate and drain-substrate coupling, then limiting the operating frequency of the transistor. A compromise is therefore achieved.

In addition, compared with Bulk technology, a layer of SiO₂ is in this case placed directly under the devices, forming the BOX. However, SiO₂ has low thermal conductivity (equal to approximately 1.4 W/m/K), which limits the discharge of heat to the solid semiconductor layer.

Alternatively, and according to the applications sought, using SOD (silicon on diamond) substrates in place of conventional SOI substrates with SiO₂ BOX is known. In these substrates, the BOX is formed by a diamond layer. However, the problems previously disclosed for SOI substrates, and in particular those related to the discharge of heat, are also found in these structures.

The document US 2003/0201492 A1 describes a circuit comprising transistors formed on a substrate comprising a stack of a solid layer of silicon and a layer of doped or intrinsic diamond disposed between the solid layer of silicon and a layer of silicon dioxide. A monocrystalline layer of silicon is disposed on the layer of oxide, forming the active layer of these transistors. This substrate is obtained by producing a deposit of diamond on the solid silicon layer, and then forming the oxide on the diamond. Because of the roughness of the diamond when the latter is produced from the solid layer of silicon, the presence of the layer of oxide is necessary to offer a flat surface enabling the monocrystalline layer of silicon to be bonded. The substrate thus obtained has in particular the drawback that:
the layer of oxide necessarily has an irregular thickness because of the roughness presented by the diamond, which creates differences in behaviour between two transistors produced alongside each other on such a substrate;
the great thickness of dielectric obscures the advantages of the layer of diamond as a thermal dissipater;
the bonding interface between the layer of oxide and the monocrystalline layer is very close to the transistors, which may give rise to interface faults and degrade the functioning of the transistors.

### DISCLOSURE OF THE INVENTION

One aim of the present invention is to propose a substrate having the advantages of a substrate of the semiconductor on insulator type compared with a solid substrate (good electrostatic control and low stray capacitances in the devices produced on this substrate; limitation of short channel effects) while optimising the discharge of heat from the devices intended to be produced on this substrate. One aim of the present invention is also to propose a substrate not having the drawbacks of the substrates of the semiconductor on insulator type, that is to say making it possible to obtain optimum electrical coupling between the rear face of the active layer and a solid layer of the substrate, in particular for producing fully depleted semiconductor devices, and between active areas of the semiconductor devices intended to be produced on this substrate and a rear layer of this substrate.

For this purpose, the present invention proposes a semiconductor substrate comprising at least:
a layer based on doped diamond,
a layer based on at least one semiconductor or a stack of layers comprising the semiconductor-based layer,
a layer based on intrinsic diamond disposed against the layer based on doped diamond, between the layer based on doped diamond and the semiconductor-based layer.

This substrate makes it possible, by virtue of the combined use of an intrinsic diamond layer, forming a buried dielectric layer and a doped diamond layer forming a rear conductive layer, to profit from the advantages of an SOI structure (BOX formed by the intrinsic diamond layer) while optimising the discharge of heat through the doped diamond layer and the intrinsic diamond layer to the outside or to an optional mechanical holding layer on which the doped diamond layer can be disposed, by virtue of the thermal properties of diamond (the thermal conductivity at ambient temperature of diamond being approximately 2000 W/m/K).

When the substrate comprises a dielectric layer between the doped diamond layer and the semiconductor layer, this structure also forms an optimum electrical interface between the active layer of the substrate, formed by the semiconductor based layer, and the intrinsic diamond layer. The intrinsic diamond layer provides electrical insulation of the semiconductor active layer, and therefore of the devices intended to be produced on this active layer, vis-à-vis the doped diamond layer. The thickness of the intrinsic diamond layer, for example between approximately 50 nm and 1 μm, also ensures optimum coupling between the rear face of the semiconductor active layer and the doped diamond layer, thus making the substrate suitable for producing fully depleted devices such as transistors.

Finally, the doped diamond layer affords good electrical contact at the rear of the intrinsic diamond layer since this layer forms a closure plane of the field lines that may be generated by the devices produced on the semiconductor active layer of the substrate, preventing the appearance of source-substrate and drain-substrate electrical couplings through the intrinsic diamond BOX.

This substrate makes it possible to benefit to the maximum extent from the high thermal conductivity of diamond using both an intrinsic diamond layer and a doped diamond layer that has a metallic behaviour, that is to say forming both a heat distributor and an electrical contact (close to the component or components intended to be produced on the substrate).

This substrate may be used for producing all types of semiconductor device, and in particular all types of transistor able to be produced on a SIO substrate such as FDSOI transistors or dual-gate transistors.

The layer based on intrinsic diamond may have a thickness of between approximately 50 nm and 1 μm and/or the layer of doped diamond may have a thickness of between approximately 0.1 μm and 700 μm.

The thickness of the doped diamond layer may be greater than or equal to approximately 10 μm, or be between approximately 10 μm and 700 μm. Thus the layer based on doped diamond may serve as a potential reference for a semiconductor device produced on the active layer based on semiconductor, the active layer of the semiconductor device being able to correspond to the semiconductor-based layer of the substrate. In this case, the layer based on doped diamond is not used as a current-conducting layer of the semiconductor device.

The substrate may also comprise a mechanical holding layer based on semiconductor and/or a dielectric material and/or resin and/or metal (for example Ti and/or Pt and/or W), according to the compatibility of the material with the methods used, the layer based on doped diamond being able to be disposed between the layer based on intrinsic diamond and said mechanical holding layer.

The stack of layers may also comprise a dielectric layer disposed between the semiconductor-based layer and the layer based on intrinsic diamond. This layer makes it possible to obtain an interface of maximum electrical quality between the active layer based on semiconductor and the BOX formed by the layer based on intrinsic diamond while avoiding the phenomena of degradation of the electrostatic performances, in particular reducing the short-channel effects, on devices intended to be produced on this substrate.

This dielectric layer may be deposited in a conformal manner on the semiconductor-based layer.

The dielectric layer may have a thickness of between 1 nm and 20 nm and/or be based on at least one material with a permittivity less than that of diamond.

The invention also concerns a method of producing a semiconductor substrate comprising at least the steps of:

a) deposition or growth of a layer based on intrinsic diamond on a layer based on at least one semiconductor or a stack of layers comprising the semiconductor-based layer,

b) deposition or growth of a second diamond-based layer on the layer based on intrinsic diamond,

c) doping of the second diamond-based layer.

Doping step c) maybe implemented simultaneously with the deposition or growth step b), for example by introducing the doping species in the plasma when the second diamond-based layer is obtained by CVD deposition.

The method may also comprise, before the deposition or growth step a), a step of producing at least one dielectric layer on the semiconductor-based layer, step a) effecting the deposition or growth of the layer based on intrinsic diamond on the dielectric layer.

The method may also comprise, between the step of producing the dielectric layer and the deposition or growth step a), a step of producing at least one nucleation layer based on at least one dielectric material (for example SiO₂ and/or Si₃N₄) and/or a semiconductor material (for example Si and/or SiC) and/or a metal material (for example Pt and/or Ti) on said dielectric layer, the nucleation layer being able to be etched completely or partially when the deposition or growth step a) is implemented. However, it is possible that said dielectric layer also fulfils the function of a nucleation layer, an additional nucleation layer then not being necessary (for example when the dielectric layer is based on Si₃N₄, thick SiO₂, etc).

The stack of layers may comprise an etching stop layer based on a dielectric or doped semiconductor material disposed against the semiconductor-based layer, the etching stop layer being able to be disposed against a semiconductor-based second layer, or solid layer. In this way an initial SOI substrate is obtained in a BESOI approach.

The method may also comprise, after a doping step c), a step of removing the second semiconductor-based layer and/or the etching stop layer.

In a variant, the method may also comprise, between the deposition or growth steps a) and b), a step of ion implantation in the semiconductor-based layer, forming a fracture interface in the semiconductor-based layer, and, after doping step c), a fracture of the semiconductor-based layer at the fracture interface.

The method may also comprise, after doping step c), a step of fixing the second layer based on doped diamond to a mechanical holding layer based on semiconductor and/or a dielectric material and/or resin. This fixing may for example be implemented by depositing the material of the holding layer on the second layer based on doped diamond, thus forming the holding layer fixed to the second layer based on doped diamond.

The method may also comprise, before the deposition or growth step a), a step of depositing a sacrificial layer based on at least one dielectric material on the semiconductor-based layer or on the stack of layers, this sacrificial layer being able to be etched during the deposition or growth step a) that is performed on the same side as the sacrificial layer.

The present invention also concerns an electronic circuit comprising at least one semiconductor device produced on the semiconductor-based layer of a substrate as described above.

The electronic circuit may also comprise a connection layer produced on the semiconductor-based layer and electrically connected to the semiconductor device.

Finally, the invention also concerns a method of producing an electronic circuit, comprising at least the steps of:

a) producing a structure comprising at least one semiconductor-based layer in which at least one semiconductor device is produced, disposed on a second layer, or solid layer, based on semiconductor,

b) fixing the semiconductor-based layer to a mechanical holding layer based on semiconductor and/or a dielectric material and/or resin,

c) removing the second semiconductor-based layer,

d) implementing a method of producing a semiconductor substrate as described above from the structure previously produced.

By producing the substrate comprising the diamond layers after the implementation of steps a), b) and c) of the method of producing the electronic circuit, it is avoided having to encapsulate the diamond layers in order to protect them from high temperatures (for example above approximately 600° C.) generated when the semiconductor device or devices of the electronic circuit are produced. In this variant, the deposits of diamond may be made at temperatures compatible with the permissible thermal budget of the semiconductor devices produced (not exceeding for example a maximum temperature of around 400° C.)

### BRIEF DESCRIPTION OF THE DRAWINGS

The present invention will be better understood from a reading of the description of example embodiments given for purely indicative and in no way limitative purpose, with reference to the accompanying drawings, in which:

FIGS. 1 and 2 show substrates with layers of intrinsic and doped diamond, that are subjects of the present invention, respectively according to a first and second embodiment,

FIG. 3 shows curves for change in the DIBL (drain induced barrier lowering) of a MOSFET transistor implemented on various types of substrate,

FIG. 4 shows curves for change in temperature in a MOSFET transistor implemented on a standard SOI substrate and on a substrate with intrinsic and doped diamond layers,

FIG. 5 shows a simulation of the change in temperature in a dual-core microprocessor produced from a substrate with intrinsic and doped diamond layers,

FIGS. 6A to 6G show the steps of a method of producing a substrate that is the subject matter of the present invention according to the first embodiment,

FIGS. 7A to 7E show the steps of a method of producing a substrate that is the subject matter of the present invention according to the second embodiment,

FIGS. 8A to 8D show the steps of another method of producing a substrate that is the subject matter of the present invention according to the second embodiment,

FIGS. 9A to 9D show the steps of a method of producing a substrate that is the subject matter of the present invention according to a third embodiment.

Identical, similar or equivalent parts of the various figures described below bear the same numerical references so as to facilitate passing from one figure to another.

The various parts shown in the figures are not necessarily to a uniform scale, in order to make the figures more legible.

The various possibilities (variants and embodiments) must be understood as not being exclusive of one another and may be combined with one another.

### DETAILED DISCLOSURE OF PARTICULAR EMBODIMENTS

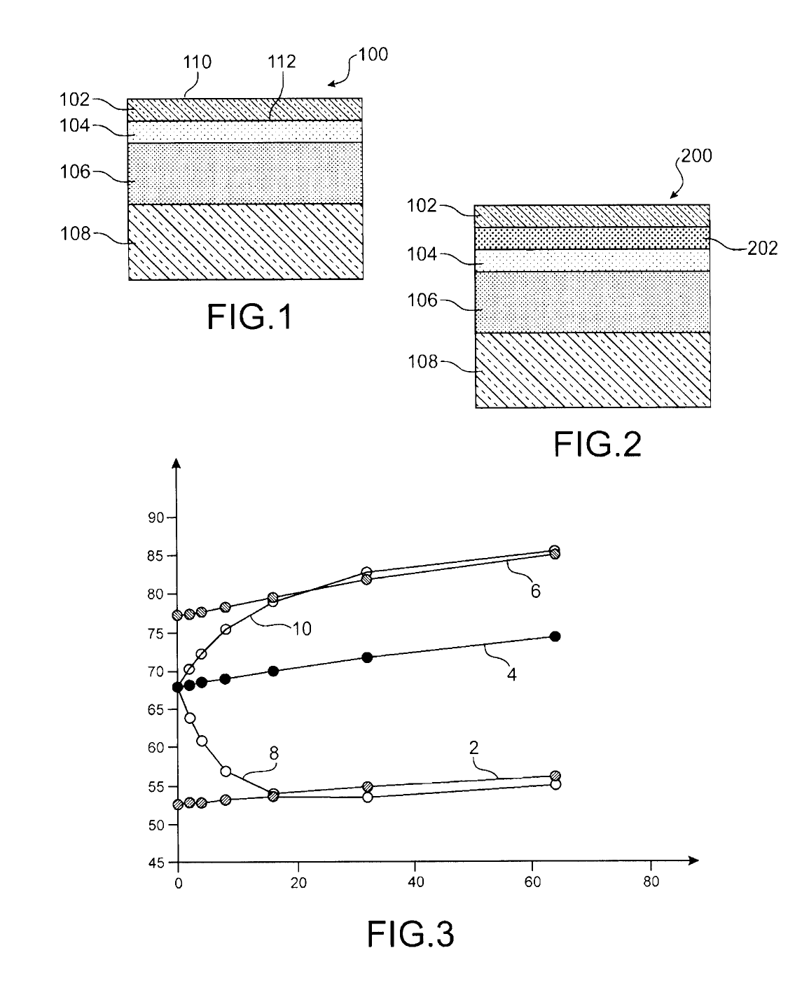

Reference is made first of all to FIG. 1, which shows a semiconductor substrate 100 according to a first embodiment.

The substrate 100 comprises an active layer 102 based on semiconductor, for example silicon and/or germanium and/or any combination of the materials in column IV of the periodic classification table of elements (SiC, SiGe, etc), or based on an alloy of materials in columns III (Ga, Al, In) and V (N, P, As, Sb) of the periodic classification table of elements (for example: GaAsₓP₁₋ₓ, GaAsₓSb₁₋ₓ, AsInₓGa₁₋ₓ, InGaₓSb₁₋ₓ, PGaₓIn₁₋ₓ, AlAsₓSb₁₋ₓ, AsAlₓIn₁₋ₓ, SbGaₓAl₁₋ₓ, disposed on a dielectric layer 104 based on intrinsic diamond and an electrically conductive layer 106 based on doped diamond. These three layers are disposed on a mechanical holding layer or stack of mechanical holding layers 108, for example based on semiconductor such as monocrystalline or polycrystalline silicon. The mechanical holding layer or stack of mechanical holding layers 108 may also be based on a dielectric material and/or resin and/or metal (for example Ti and/or Pt and/or W), or more generally any material compatible with the methods used for producing the substrate 100.

The active layer 102 has a thickness of between approximately 5 nm and 1 μm. The intrinsic diamond layer 104 has a thickness of between approximately 50 nm and 1 μm. The diamond of the layer 104 may be monocrystalline or polycrystalline. The polycrystalline diamond may be composed of columnar grains or a stack of nanograins (nanocrystalline diamond). A nanocrystalline diamond has less roughness than a polycrystalline diamond with a columnar structure. On the other hand, a nanocrystalline diamond has more grain joints than a polycrystalline diamond, which may reduce its thermal conductivity.

The electrically conductive layer 106 based on doped diamond has a thickness of between approximately 0.1 μm and 700 μm or between 20 μm and 500 μm. The thickness of the layer of doped diamond 106 may in particular be chosen according to the application of this substrate 100 as well as other industrial considerations such as the cost and growth rate of the diamond of this layer 106. The diamond of the layer 106 is doped, for example with boron or any species for conferring an electrically conductive behaviour on the diamond layer 106. When boron is used for effecting the doping of the diamond layer 106, then an n-type doping is performed for example equal to or greater than approximately 10²¹ cm⁻³ in order to ensure a metallic behaviour for the diamond layer 106. When the layer 106 is n-type doped, for example by phosphorus or a hydrogenated boron complex, this doping may also be equal to or greater than approximately 10²¹ cm⁻³ in order to ensure a metallic behaviour for the diamond layer 106. The mechanical holding layer 108 may have a thickness of between approximately 300 μm and 700 μm, according to the diameter of the substrate.

In a variant of this first embodiment, the substrate 100 may not comprise the mechanical holding layer 108, in particular when the diamond layers 104 and 106 have a total thickness greater than or equal to approximately 500 μm, or more generally a thickness for ensuring sufficient mechanical holding for the substrate 100. In another variant, the substrate 100 may also comprise a buffer layer disposed between the mechanical substrate 108 and the diamond layer 106 ensuring adhesion between the doped diamond layer 106 and the mechanical holding layer 108.

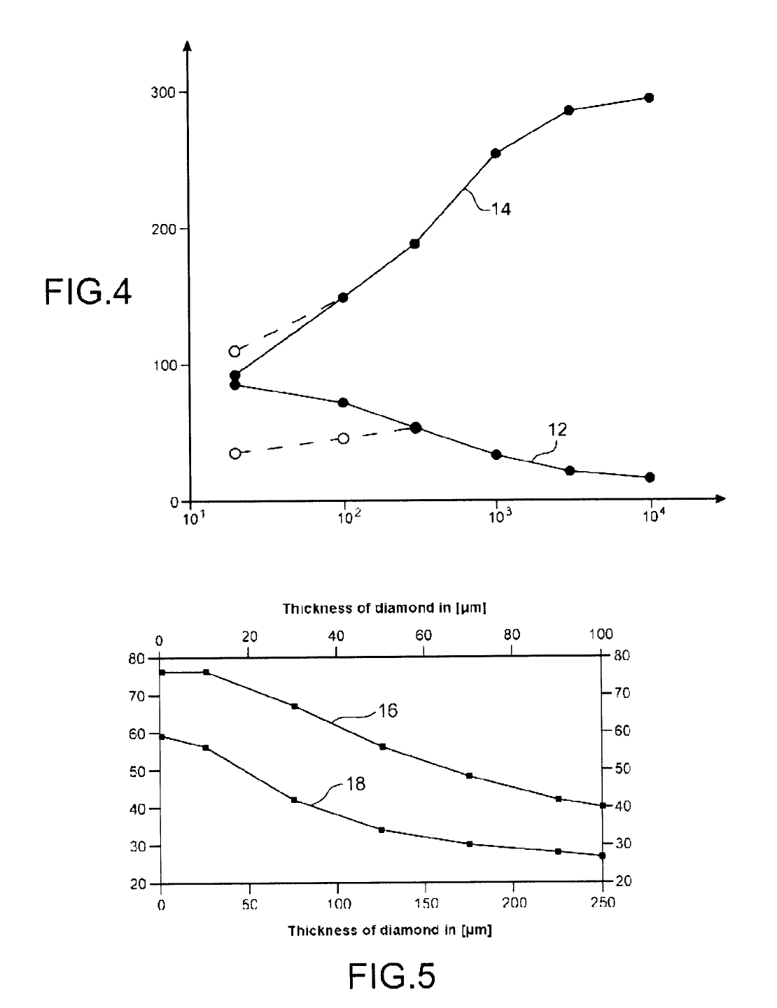

FIG. 2 shows a substrate 200 according to a second embodiment. The substrate 200 comprises the layers 102 to 108 previously described in relation to the substrate 100 shown in FIG. 1. Compared with the substrate 100, the substrate 200 comprises an additional dielectric layer 202, for example based on SiO₂ and/or SiC disposed between the active layer 102 and the intrinsic diamond layer 104

and with a thickness of between approximately 1 nm and 100 nm, and preferentially between approximately 1 nm and 20 nm. The dielectric layer 202 is preferably produced from a material with a permittivity less than that of diamond in the case of an FDSOI transistor.

These two substrates 100 and 200 comprise a buried dielectric, or BOX, formed by the intrinsic diamond layer 104 producing the electrical insulation of the active layer 102 vis-à-vis the doped diamond layer 106. From an electrical point of view, the presence of this intrinsic diamond layer 104 modifies the electrostatics of a semiconductor device, for example a fully depleted transistor, implemented on one of these substrates 100 and 200, compared with the same transistor implemented on a conventional SOI substrate. This is because, in this type of transistor, the couplings between a front face (reference 110 in FIG. 1) and a rear face (reference 112 in FIG. 1) of the active layer 102 act with regard to electrostatic control and short channel effects of the transistor. Compared with a Box based on SiO₂, a BOX based on diamond has a slightly greater permittivity (permittivity of diamond=5.5; permittivity of SiO₂=3.9), the impacts on the DIBL and the current I_{off} of the transistor implemented on this substrate being low. Diamond therefore presents a very good compromise between high thermal conductivity and low electrical permittivity.

The presence of the dielectric layer 202, which is here based on a material with a permittivity less than that of diamond, reduces the short-channel effects on the transistors implemented on this substrate, avoiding the phenomena of degradation of the electrostatic performances with regard to the interface with the optimum rear face of the transistor.

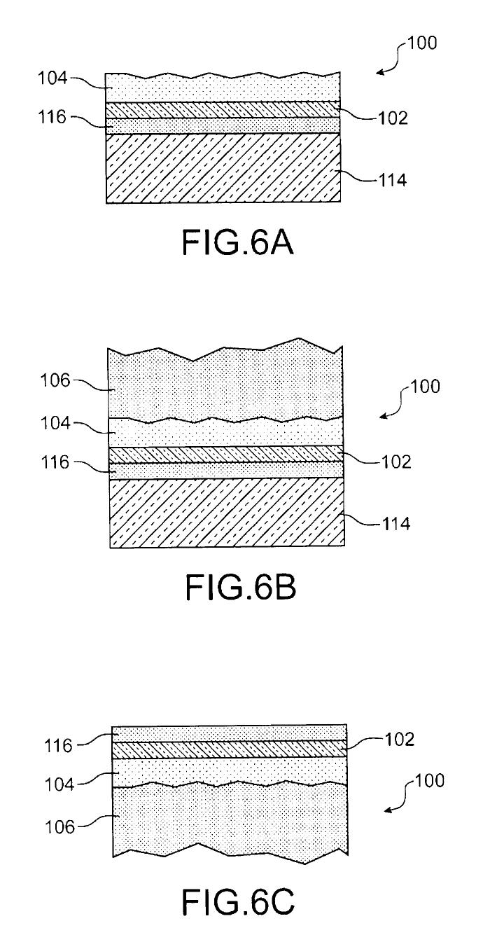

FIG. 3 shows the change in the DIBL for transistors of the nMOSFET type with a gate length of approximately 25 nm on a layer of silicon 102 with a thickness of approximately 5 nm, produced on the substrate 200, according to the thickness of the dielectric layer 202 and the nature of the material of the layer 202. In order to be able to compare these results, the curves 2, 4 and 6 represent respectively the change in the DIBL (in mV/V on the Y-axis) of such a transistor implemented on an SOI substrate comprising a BOX based on SiO₂ (curve 2), diamond (curve 4) or BeO (curve 6), according to the thickness of the BOX (in nm on the X-axis). Curves 8 and 10 represent the change in DIBL of this same transistor implemented on the substrate 200 comprising an intrinsic diamond layer with a thickness of approximately 100 nm and a dielectric layer 202 based on SiO₂ (curve 8) or BeO (curve 10) disposed between a layer of silicon 102 with a thickness of approximately 5 nm and the intrinsic diamond layer, according to the thickness (in nm on the X-axis) of this dielectric layer 202.

Given that BeO has a permittivity (approximately 6.7) greater than that of diamond (approximately 5.7), curve 10 shows clearly that the presence of a layer 202 based on a material with a permittivity greater than that of diamond increases the DIBL of a transistor implemented on such a substrate 200. On the other hand, when this layer 202 is based on a material with a permittivity less than that of diamond, such as SiO₂, it is then possible to reduce this DIBL and therefore to reduce the short-channel effects on this transistor. In general terms, this effect is observed whatever the thickness of the intrinsic diamond layer 104 (for example between approximately 50 nm and 1 μm) and whatever the length of the channel of the transistor (for example approximately 20 nm, 50 nm or 100 nm).

The dielectric layer 202 present in the substrate 200 therefore appreciably reduces the short-channel effects, even when it has a low thickness, for example approximately 10 nm.

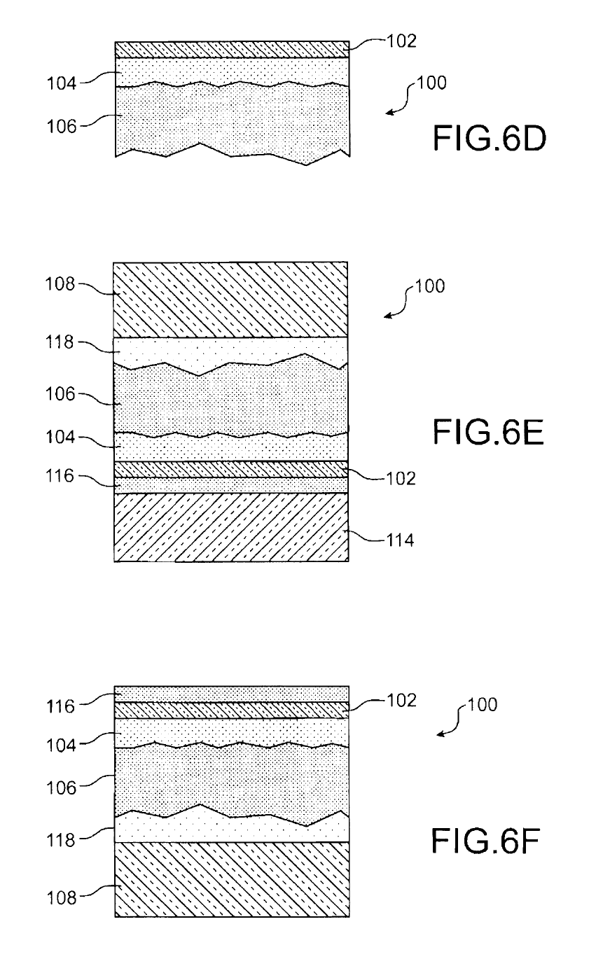

The use of a BOX based on intrinsic diamond improves the heat dissipation in the substrate compared with the use of a BOX based on SiO₂. FIG. 4 illustrates this, presenting the change in temperature (in Kelvin on the Y-axis) at the drain of a MOSFET dissipating approximately 1 mW/μm implemented on an SOI substrate comprising a BOX of SiO₂ (curve 14) and on the substrate 100 (curve 12), that is to say comprising a BOX of intrinsic diamond and a doped diamond layer, as a function of the thickness of the BOX (in nm on the X-axis). These two layers show that a BOX based on intrinsic diamond reduces the rise in heat more effectively than a buried oxide layer (thick or thin), without reducing the speed of functioning or switching of the transistor.

In addition, in the case of the substrate 200 comprising an additional dielectric layer 202 based on SiO₂ disposed between the intrinsic diamond layer 104 and the semiconductor active layer 102, the temperature of a transistor implemented on the active layer 102 is also significantly reduced, in particular when the dielectric layer 202 has a thickness less than or equal to approximately 10 nm.

The stack formed by the intrinsic diamond layer 104 and the doped diamond layer 106 does not have any interface resistance since the materials in contact with each other are of the same nature. This therefore optimises the thermal dissipation through the substrate.

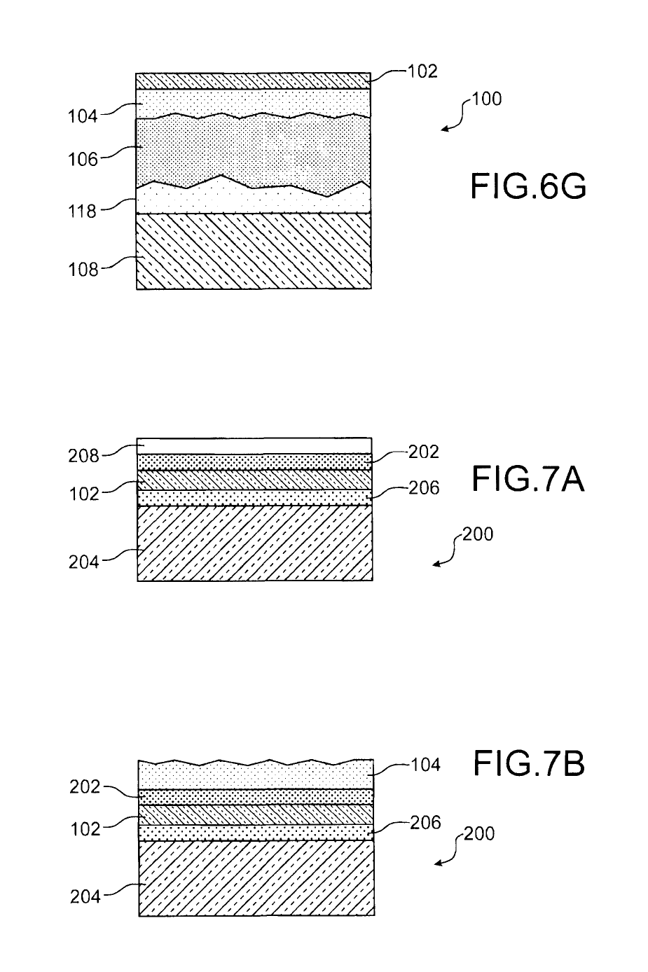

This better thermal dissipation is also found in devices produced from such a substrate. FIG. 5 shows a simulation of the change in temperature in a dual-core microprocessor produced with a realistic environment and heat generation map (as described in the document “Analytical modelling for prediction of hot spot chip junction temperature for electronics cooling applications” by M Iyengar et al, IEEE Itherm Conference, 2006). These simulations are implemented for a substrate with a structure similar to the substrate 100 and with a total thickness of 100 μm (curve 16) or 250 μm (curve 18), the change in the temperature (in Kelvin on the Y-axis) being shown as a function of the total thickness of diamond in the substrate (in μm on the X-axis).

The substrates tend to be thinned so that the encapsulated chips are as thin as possible. As shown in FIG. 5, a substrate with a thickness of approximately 100 μm gives rise to an increase in maximum temperature of the circuit of 15° K compared with a substrate with a thickness of approximately 250 μm (since a lesser thickness involves less heat spread effect). This increase in temperature can be cancelled out by including 40 μm of diamond in the substrate, thus increasing its capacity to direct the heat laterally in the chip, thus offering a larger effective discharge cross section.

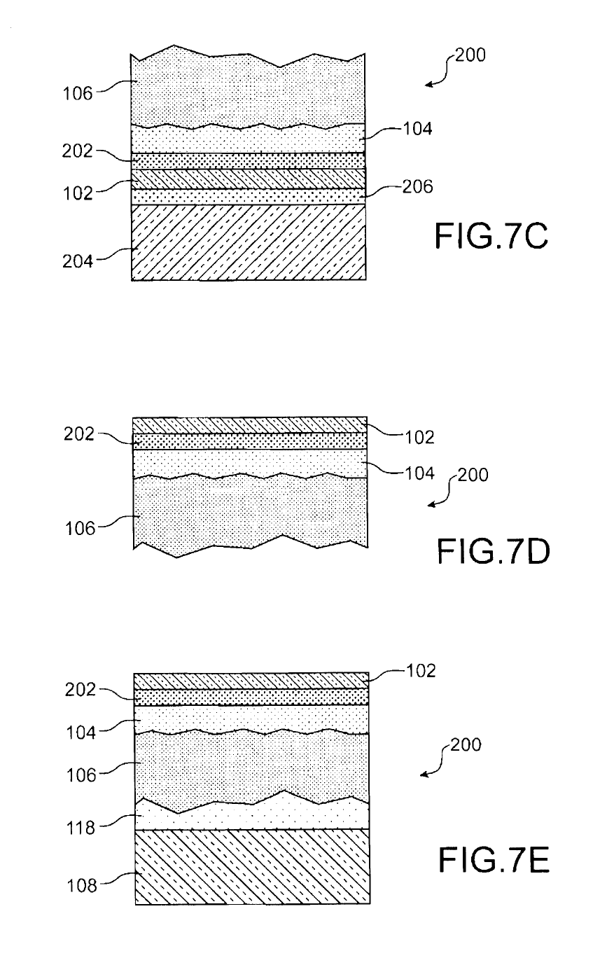

Reference is now made to FIGS. 6A to 6G, which show the steps of a method of producing the substrate 100 according to the first embodiment.

As shown in FIG. 6A, first of all a dielectric layer 104 based on diamond is deposited on an active layer 102 based on semiconductor, for example silicon and/or germanium and/or any other semiconductor. The active layer 102 is the top layer of a stack comprising a solid layer 114 based on semiconductor, for example silicon, that is to say the mechanical holding layer of an initial SOI substrate, on which an etching stop layer 116 is disposed, the active layer 102 being disposed on the etching stop layer 116. The solid layer 114 has thickness of between approximately 300 μm and 700 μm. In general terms, solid layer means a layer the thickness of which is equal to or greater than approximately 10 μm. The etching stop layer 116 is for example produced from a dielectric material such as SiO₂ and/or Si₃N₄, and/or highly doped semiconductor, for example silicon, and has a thickness of between approximately 10 nm and 1 μm. The diamond dielectric layer 104 can be deposited by MPCVD (microwave plasma assisted chemical vapour deposition), HFCVD (hot filament chemical vapour deposition) or any other technique suited to the deposition of diamond. The diamond layer 104 can also be produced by growth on the active layer 102.

In FIG. 6B, a diamond layer 106 is deposited or produced by growth on the intrinsic diamond layer 104, and doped for example by doping with boron or any other chemical species suitable for conferring on the diamond layer 106 a metallic character, that is to say an electrically conductive behaviour.

When the diamond layers 104 and 106 are sufficiently thick (the total thickness of the layers 104 and 106 being for example greater than or equal to approximately 500 μm) in order to ensure sufficient mechanical holding for the substrate 100, the solid layer 114 is then removed, for example by polishing, grinding, chemical attack or any other technique suited to such removal, as shown in FIG. 6C. The etching stop layer 116 is then removed by one of the previously mentioned techniques for removing the solid layer 114 or any other technique suited to such a removal (FIG. 6D).

When the diamond layers 104 and 106 do not provide sufficient mechanical holding of the substrate 100 (for example when the total thickness of the layers 104 and 106 is less than approximately 500 μm), the previously formed structure (shown in FIG. 6B) is transferred either directly by deposition on a mechanical holding layer 108 or, as shown in FIG. 6E, transferred onto the layer 108 by means of a buffer layer 118, in particular when said structure is attached by bonding. The buffer layer 118 in particular “absorbs” the roughness that may be present at the face of the doped diamond layer 106 intended to be on the same side as the mechanical holding layer 108.

Finally, as previously described in relation to FIGS. 6C and 6D, the solid layer 114 is removed (FIG. 6F) and then the etching stop layer 116 is removed (FIG. 6G).

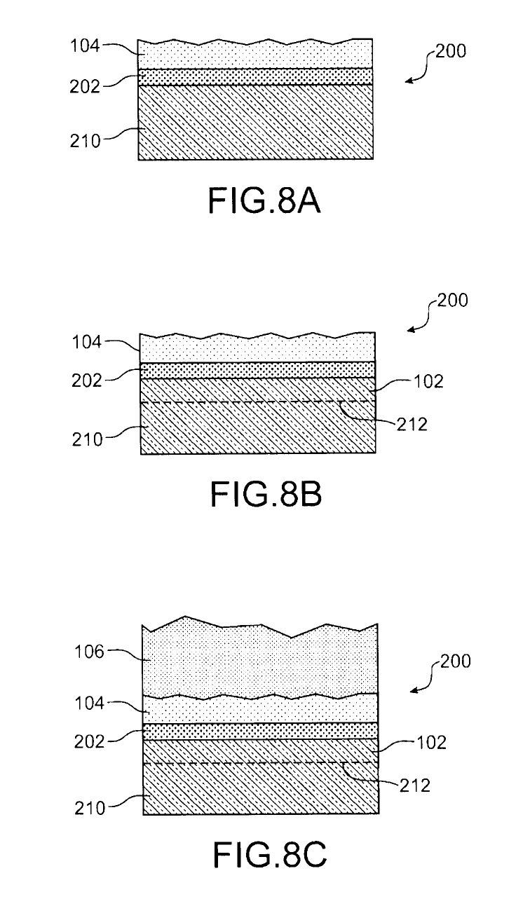

Reference is now made to FIGS. 7A to 7E, which show the steps of a method of producing the substrate 200.

In FIG. 7A, a dielectric layer 202 is deposited on a substrate of the semiconductor on insulator type comprising a solid layer 204 based on a semiconductor material such as silicon and/or germanium, on which a dielectric layer 206 and an active layer 102 of semiconductor are disposed. The dielectric layer 202 is here a thin layer having a thickness of between approximately 1 nm and 20 nm.

In the example in FIG. 7A, a nucleation layer 208 based on dielectric material (for example SiO₂ and/or Si₃N₄ and/or TiO₂), and/or a semiconductor material (for example Si and/or SiC and/or Ge) and/or a metal material (for example Pt and/or Ti and/or Ir and/or Ni and/or Mo and/or Au and/or W), which will subsequently serve as a barrier and/or precursor when the intrinsic diamond layer 104 is produced, is deposited on the dielectric layer 202. This nucleation layer has for example a thickness of between approximately 1 nm and 100 nm, and preferably between approximately 5 nm and 50 nm.

This nucleation layer may advantageously be removed during the diamond growth step, the objective therefore being to minimise or even cancel out the thickness of this material during the growth of the diamond while preserving the integrity of the dielectric layer. In order to calculate the thickness of the nucleation layer 208, it is possible to perform the following steps:
from a solid semiconductor substrate, the dielectric layer 202 is deposited with the required thickness and then a layer of the nucleation material is deposited with a thickness of approximately 10 nm;
the growth of the diamond 104 is next effected on the nucleation layer and then the integrity of the dielectric layer 202 is checked, for example by measurements of the electrical conductivity and/or of the residual thickness of the dielectric layer 202, with respect to a previously fixed criterion (for example a maximum electrical conductivity level or a minimum residual thickness). Two cases then present themselves:
if this integrity is verified, a new deposition of diamond is then effected with a nucleation layer 1 nm less thick than before and the integrity of the dielectric is checked. This procedure is followed until it is no longer possible to ensure the integrity fixed;
if this integrity is not verified, a new substrate is then produced with deposition of the dielectric layer and deposition of the nucleation layer 1 nm thicker than before and the integrity is checked after the growth of the diamond. This procedure is followed until the integrity that has been fixed is ensured.

In this way the optimum thickness of the nucleation layer 208 is obtained.

As shown in FIG. 7B, the growth of the diamond layer 104 on the previously produced structure is effected. The growth of the diamond on some materials, for example SiO₂, may etch and damage these materials, which is prejudicial for the production of the substrate 200. Because of the presence of the sacrificial layer 208, the integrity of the dielectric layer 202 is preserved by virtue of the sacrificial role of the layer 208. By choosing a layer 208 with a thickness of between approximately 1 nm and 10 nm, the growth of the diamond layer 104 gives rise to the total or partial elimination of the layer 208, the intrinsic diamond layer 104 being formed on the dielectric layer 202.

As for the production of the substrate 100, the growth or deposition of the diamond layer 106 is then effected on the intrinsic diamond layer 104, and the doping of this diamond layer 106 so that the latter becomes electrically conductive (FIG. 7C).

Finally, the substrate 200 is completed in a similar manner to the substrate 100 by effecting either directly the removal of the solid layer 204 and of the dielectric layer 206 when the thicknesses of the diamond layers 104 and 106 are sufficient to ensure mechanical holding of the substrate 200 (FIG. 7D), or effecting the transfer of the structure produced onto a mechanical holding layer 108 (possibly by means of a buffer layer 118) before removing the solid layer 204 and the dielectric layer 206 (FIG. 7E).

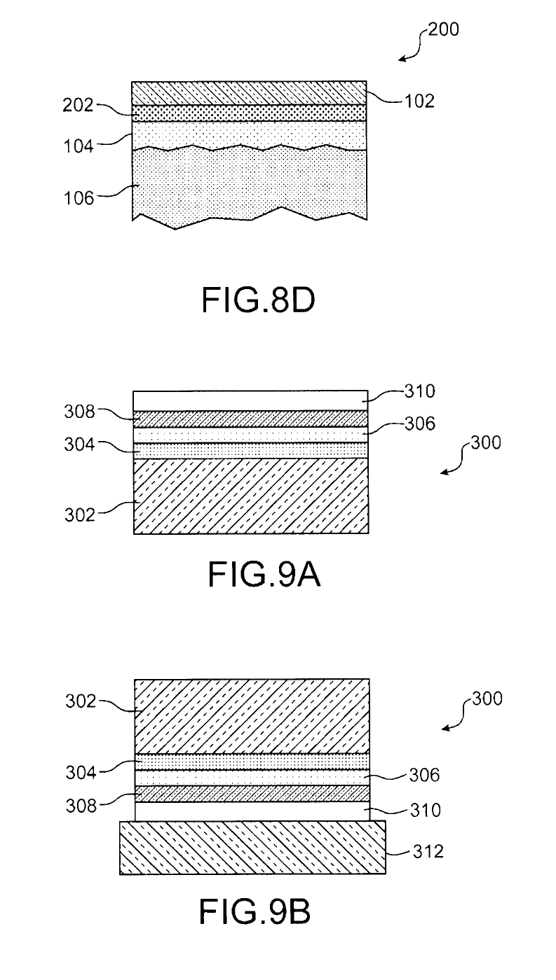

In a variant of the embodiments described previously, the substrates 100 and 200 can be produced not from a substrate of the semiconductor on insulator type, as described in relation to FIGS. 6A to 6G and 7A to 7E, but from a semiconductor-based solid substrate. FIGS. 8A to 8D show the steps of such a production method for the substrate 200.

In FIG. 8A, the deposition or growth of a layer of intrinsic diamond 104 is effected on a dielectric layer 202 disposed on a solid semiconductor-based substrate 210 such as silicon. As in the method described previously in relation to FIGS. 7A and 7E, the growth of the diamond layer 104 can be effected on a stop layer previously deposited on the dielectric layer 202, similar to the previously described layer 208.

A ion implantation is then effected in the solid substrate 210, forming a fracture interface 212 in it (FIG. 8B). The part of the solid substrate 210 situated between the dielectric layer 202 and the fracture interface 212 is intended to form the active layer 102.

The growth of a doped diamond layer 106 is then proceeded with at low temperature, that is to say at a temperature of between approximately 200° C. and 500° C., or preferably between approximately 300° C. and 400° C., in order to improve the quality of the doped diamond layer 106, so as to avoid fracturing the solid substrate 210 at the interface 212 (FIG. 8C). Finally, the active layer 102 is separated from the rest of the substrate 210 by fracture at the interface 212 (FIG. 8D).

As in the methods previously described, it is possible, before effecting the separation of the active layer 102 from the rest of the solid substrate 210, when the diamond layers 104 and 106 do not have sufficient thickness to provide the mechanical holding of the substrate 200, to transfer this structure onto a mechanical holding layer 108, possibly by means of a buffer layer 118 between the electrically conductive diamond layer 106 and the mechanical holding layer 108.

In a similar manner to the method described above in relation to FIGS. 8A to 8D, it is also possible to produce the substrate 100 from a solid substrate 210. For this purpose, the intrinsic diamond layer 104 is directly produced on the solid substrate 210 rather than on a dielectric layer 202. The steps performed are then similar to those previously described in relation to FIGS. 8B to 8D.

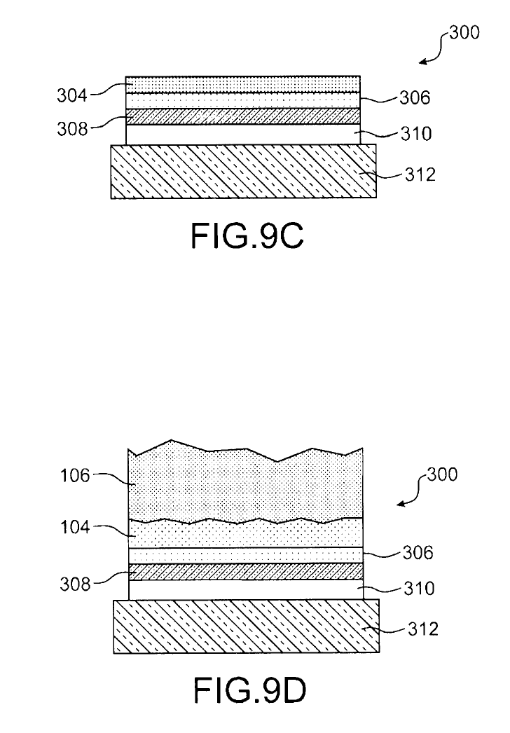

The substrate with intrinsic and doped diamond layers can be used for producing a circuit comprising integrated semiconductor components. FIGS. 9A to 9D show the steps of a method of producing an electronic circuit 300 according to a particular embodiment, using a substrate with intrinsic and doped diamond layers such as one of the substrates 100 and 200 described previously.

As shown in FIG. 9A, first of all a structure of the semiconductor on insulator type is produced, comprising a solid layer 302 based on semiconductor, for example silicon, on which there are stacked a dielectric layer 306, for example based on SiO₂ and with a thickness of between approximately 1 nm and 20 nm, an active layer 308 in which active components (for example transistors) are produced, and a layer of electrical connections 310 electrically connected to the components of the active layer 308. In the example described here, a sacrificial layer 304, intended to protect the dielectric layer 306 during a subsequent deposition of diamond, is disposed between the solid layer 302 and the dielectric layer 306.

In FIG. 9B, a mechanical holding layer 312, for example based on resin or a dielectric material such as SiO₂ or based on semiconductor, is temporarily fixed to the connection layer 310.

The solid layer 302 is then removed from the structure, for example by polishing, grinding, chemical attack or any other suitable technique (FIG. 9C).

In a similar manner to the embodiments previously described, the growth of the intrinsic diamond layer 104 on the dielectric layer 306 is effected, this growth causing the elimination of the sacrificial layer 304, then the growth or deposition of the diamond layer 106 on the intrinsic diamond layer 104 and the doping of the diamond layer 106 so that the latter becomes electrically conductive (FIG. 9d). It is then possible to remove the mechanical holding layer 312 in order to encapsulate the circuit 300.

In a variant, the intrinsic diamond layer 104 may be deposited directly on the dielectric layer 306 or on the silicon layer 308.

1-14. (canceled)

15. A semiconductor substrate comprising:
a layer based on doped diamond with a thickness greater than or equal to approximately 10 μm;
a stack of layers comprising a layer based on at least one semiconductor-based layer;
a layer based on intrinsic diamond disposed against the layer based on doped diamond, between the layer based on doped diamond and the semiconductor-based layer;
the stack of layers further comprising a dielectric layer disposed between the semiconductor-based layer and the layer based on intrinsic diamond.

16. The semiconductor substrate according to claim 15, the layer based on intrinsic diamond having a thickness of between approximately 50 nm and 1 μm and/or the layer of doped diamond having a thickness of between approximately 10 μm and 700 μm.

17. The semiconductor substrate according to claim 15, further comprising a mechanical holding layer based on semiconductor and/or a dielectric material and/or resin and/or metal, the layer based on doped diamond being disposed between the layer based on intrinsic diamond and the mechanical holding layer.

18. The semiconductor substrate according to claim 15, the dielectric layer having a thickness of between approximately 1 nm and 20 nm and/or being based on at least one material with a permittivity less than that of diamond.

19. A method of producing a semiconductor substrate, comprising:
a) producing at least one dielectric layer on a semiconductor-based layer based on at least one semiconductor, forming a stack of layers;
b) deposition or growth of a layer based on intrinsic diamond on the dielectric layer;
c) deposition or growth of a second diamond-based layer with a thickness greater than or equal to approximately 10 μm on the layer based on intrinsic diamond; and
d) doping of the second diamond-based layer.

20. The method according to claim 19, in which the doping d) is implemented simultaneously with the deposition or growth b).

21. The method according to claim 19, further comprising, between the a) producing the dielectric layer and the deposition or growth b), producing at least one nucleation layer based on at least one dielectric material and/or a semiconductor material and/or a metal material on the dielectric layer, the nucleation layer being etched completely or partially during implementation of the deposition or growth b).

22. The method according to claim 19, in which the stack of layers comprises an etching stop layer based on a dielectric or doped semiconductor material disposed against the semiconductor-based layer, the etching stop layer being disposed against a second semiconductor-based layer.

23. The method according to claim 22, further comprising, after the doping c), e) removing the second semiconductor-based layer and/or the etching stop layer.

24. The method according to claim 19, further comprising, between the deposition or growth b) and c), ion implantation in the semiconductor-based layer, forming a fracture interface in the semiconductor-based layer, and after the doping d), e) a fracture of the semiconductor-based layer at the fracture interface.

25. The method according to claim 19, further comprising, after the doping d), e) fixing the second layer based on doped diamond to a mechanical holding layer based on semiconductor and/or a dielectric material and/or resin.

26. An electronic circuit comprising:
at least one semiconductor device produced on the semiconductor-based layer of a substrate according to claim 15.

27. The electronic circuit according to claim 26, further comprising a connection layer produced on the semiconductor-based layer and electrically connected to the semiconductor device.

28. A method of producing an electronic circuit, comprising:
a) producing a structure comprising at least one semiconductor-based layer in which at least one semiconductor device is produced, disposed on a second semiconductor-based layer;
b) securing the semiconductor-based layer to a mechanical holding layer based on semiconductor and/or a dielectric material and/or resin;
c) removing the second semiconductor-based layer;
d) implementing a method of producing a semiconductor substrate according to claim 19 from the structure previously produced.
